(19) United States
(12) Patent Application Publication
(10) Pub. No.: US 2023/0058812 A1
(43) Pub. Date: Feb. 23, 2023

(54) SUPPORT STRUCTURES FOR COMPUTING COMPONENTS

(71) Applicant: HEWLETT-PACKARD DEVELOPMENT COMPANY, L.P., Spring, TX (US)

(72) Inventors: Tien Liang Chung, Taipei City (TW); Hsing Hao Chen, Taipei City (TW)

(73) Assignee: HEWLETT-PACKARD DEVELOPMENT COMPANY, L.P., Spring, TX (US)

(21) Appl. No.: 17/796,860

(22) PCT Filed: Jan. 31, 2020
(86) PCT No.: PCT/US2020/016202

§ 371 Date: Aug. 1, 2022

(51) Int. Cl. G06F 1/18; G06F 1/16; H05K 7/16

(52) U.S. Cl. CPC G06F 1/187; G06F 1/1658; H05K 7/16

(57) ABSTRACT

According to an example, a device housing may have a support structure to hold a removably mounted computing component. The support structure may comprise a first rotatably mounted arm comprising a first post and a resilient biasing element attached to the arm. The resilient biasing element may bias the first arm in a direction towards engagement with the computing component such that the first post such that the first post holds the computing component in place.

### BACKGROUND

Electronic devices such as computing devices may comprise a large number of computing components. These computing components may be attached to or disposed within a housing of the computing device, however, sometimes the computing components may need to be removable. To assure that removable components can be extracted properly, a variety of support structures may be used.

### BRIEF DESCRIPTION OF DRAWINGS

Features of the present disclosure are illustrated by way of example and are not limited in the following figure(s), in which like numerals indicate like elements, in which:

FIG. 1 shows a device housing having a support structure for a computing component, according to an example of the present disclosure;

FIG. 2 shows a device housing having a support structure, according to an example of the present disclosure;

FIG. 3 shows an inner surface of a device housing and a support structure for a computing component, according to an example of the present disclosure;

FIG. 4 shows a front view of a support structure, according to an example of the present disclosure;

FIG. 5 shows a rear view of the support structure of FIG. 4;

FIG. 6 shows an inner surface of a device housing and a support structure, according to an example of the present disclosure.

### DETAILED DESCRIPTION

For simplicity and illustrative purposes, the present disclosure is described by referring mainly to examples. In the following description, numerous specific details are set forth in order to provide a thorough understanding of the present disclosure. It will be readily apparent, however, that the present disclosure may be practiced without limitation to these specific details. In other instances, some methods and structures have not been described in detail so as not to unnecessarily obscure the present disclosure.

Throughout the present disclosure, the terms “a” and “an” are intended to denote at least one of a particular element. As used herein, the term “includes” means includes but not limited to, the term “including” means including but not limited to.

Disclosed herein are examples of computers comprising support devices to hold computing components. Hence, different examples of support devices and computers are described.

Desktop computers and all-in-one computers comprise device housings to contain computing components. Among other things, factors that determine the size and the shape of device housings are the number and the size of computing components contained within their inner volume. Computing components are attached somehow so that the integrity of the computer is assured. Since the inner volume of a computer is limited, computing components are attached so that the space specifications are satisfied.

In order to support computing components, structural frames and structures are used within the computing device. However, since some of the components may need to be extracted, attachments are used. Those attachments enable a user to extract a specific computing component without needing the assistance of extra tools.

Among other components, computing components that may need to be removable are storage drives. As a result, storage drives are often attached to the computer by a removable attachment. Storage drives may have a cuboid shape, however, other shapes may be possible.

Throughout this description, the term “storage drive” refers generally to hardware that stores data without power until purposely erased. Examples of storage drive comprise hard drives and solid-state drives.

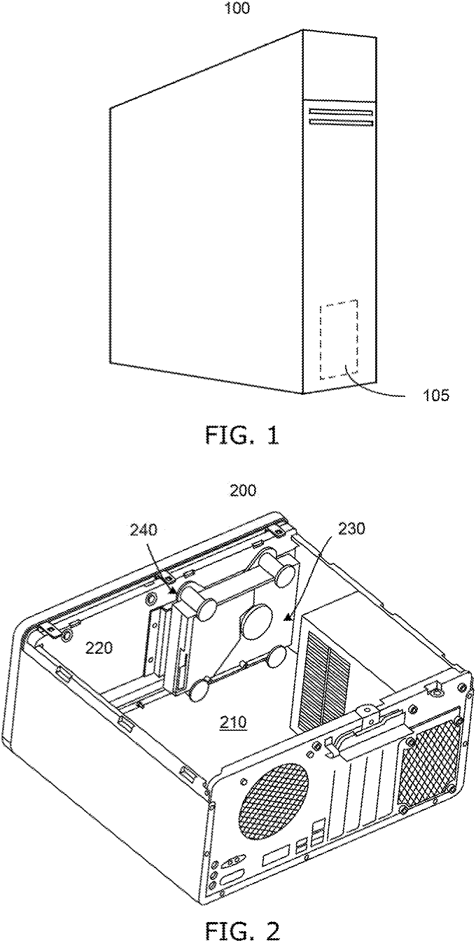

Referring now to FIG. 1, a computer 100 is shown. The computer 100 comprises a device housing which is oriented in a vertical direction. However, in other examples, the device housing of the computer 100 may be oriented in a horizontal direction. The computer 100 comprises walls defining an inner volume in which computing components are disposed. As previously described, since the inner volume of the computer 100 is limited, the computing components’ dimensions and their distribution are a fundamental part of the design. The device housing of the computer 100 comprises a support structure 105 to hold a removably mounted computing component. The support structure may be disposed within the inner volume of the device housing. In an example, the support structure may be comprised, for instance, on inner surfaces of the computer 100. In other examples, computing components supports may be provided in internal mounts, stands, racks, inner walls, external frames or holders. In other examples, computers may be alternatively referred to as computing devices.

Since some of the computing components may need to be attached in a demountable way, removable support structures are used. As described previously, an example of a computing component that may need to be removably attached is a storage drive.

In FIG. 1, the computer 100 corresponds to a desktop computer. However, in other examples, the computer can be any other kind of computer having a device housing, for instance, an all-in-one computer.

Referring now to FIG. 2, a device housing 200 comprising walls defining an inner volume 210 is shown. The computing components may be disposed within the inner volume 210 of the device housing 200. In the example of FIG. 2, the device housing 200 is opened by one of its sidewalls. Depending on the dimensions of the device housing 200, the inner volume 210 may allow a different number of computing components and/or distributions. The device housing 200 comprises an inner surface 220 and a support structure 240 in which a storage drive 230 is removably attached. Since a support structure 240 enables a removable attachment of the storage drive 230, the storage drive 230 can be extracted from the housing 200 without needing additional tools. In other examples, the storage drive 230 may be replaced for other computing components.

The storage drive 230 may be connected to other computing components within the inner volume 210 of the device housing 200. However, FIG. 2 is not showing any computing component connected to the storage drive for clarity purposes.

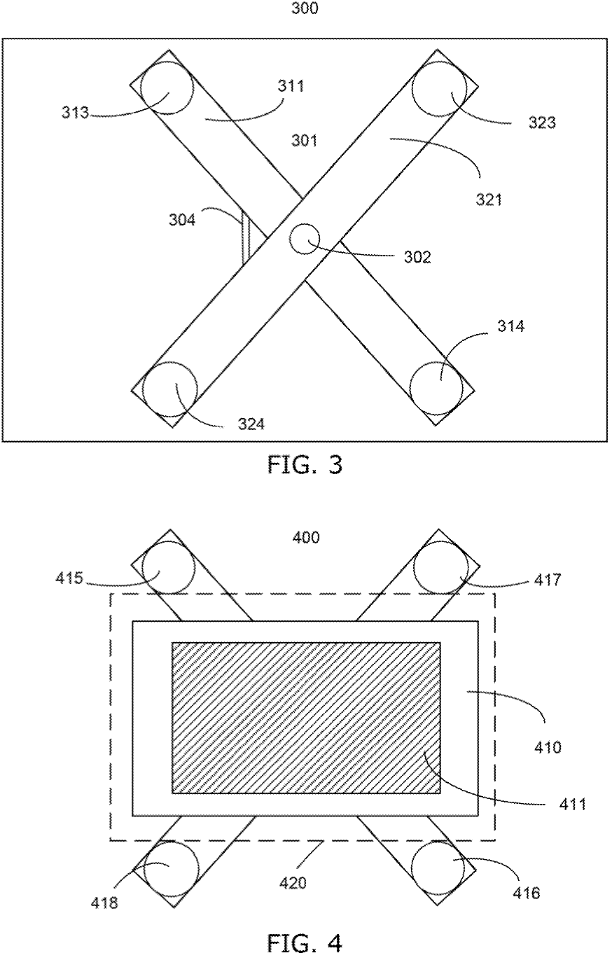

Referring now to FIG. 3, an inner surface 300 and a support structure 301 are shown. The inner surface 300 may be the inner surface described previously in reference to FIG. 2. However, for simplicity purposes, in FIG. 2 is not shown the device housing. In other examples, the inner surface 300 may correspond to an inner surface of an all-in-one computer. The support structure 301 provides removable support for a computing component (not shown in FIG. 3). In the example of FIG. 3, the support structure 301 is attached to the inner surface 300 of the device housing. However, in other examples, the support structure 301 may be attached to a different element, e.g., a structural frame or an internal mount.

The support structure 301 comprises a first rotatably mounted arm 311 and a second rotatably mounted arm 321. Both arms are rotatably attached through a pivot element 302. The first arm 311 comprises a first post 313 and a second post 314. The second arm 321 comprises a third post 323 and a fourth post 324. A resilient biasing element 304 is attached to the first arm 311 and the second arm 321. The resilient biasing element 304 biases the arms in a direction towards engagement with the computing component such that the first post 313, the second post 314, the third post 323, and the fourth post 324 hold the computing component (not shown in FIG. 3) in place. The engagement comprise the contact points between the posts and the computing component. In other examples, the resilient biasing element 304 biases the arms laterally so that the posts can hold a computing component (not shown in FIG. 3) in place. The resilient biasing element 304 may exert a reaction force which is transmitted to the computing component through the engagements. As a result, the computing component is held in place. The first post 313 together with the third post 323 may contact a first side of the computing component and the second post 314 together with the fourth post 324 may contact a second side of the computing component. Therefore, the first post 313, the second post, 314, the third post 323, and the fourth post 324 can hold the computing component in place.

In an example, the computing component is a cuboid storage drive and the arms rotate about an axis perpendicular to the largest face of the storage drive. The first side and the second side contacted by the posts correspond to the lateral sides of the storage drive.

According to some examples, the FIG. 3 configuration may be referred to as an X-shape configuration. X-shape configuration may be understood as the reference of the position of the first arm relative to the second arm, wherein both arms are rotatable about a single pivot element.

Resilient biasing elements can include, amongst others, elastic elements, resilient elements, or any element capable of recovering size and shape after a deformation, for example, a deformation caused by the process transmitted forces.

Referring now to FIG. 4, a front view of a support structure 400 comprising a plate 410 is shown. For illustrative purposes, the inner surface described previously in the description is not shown. The support structure 400 may be disposed within an inner volume of a computer. A computing component 420 is represented in dashed lines so that the plate 410 can be seen from the front view of the support structure 400. In some examples, the computing component 420 is a cuboid storage drive. The plate 410 comprises a vibration absorbent material 411 attached on a plate face that is facing the computing component 420. The vibration absorber material 411 reduces the force transmission between the computing component 420 and the support structure 400. Although a rectangular shape is used for the plate 410 and the vibration absorber material 411 in FIG. 4, in other examples different configurations for the plate 410 and/or the vibration absorbent material 411 are possible. The side of the plate 410 which comprises is facing the computing component 420 may be referred to as a first side. The support structure 400 may correspond to the example previously described in reference to FIG. 3, and therefore, the computing component 420 is held in place by a first post 415, a second post 416, a third post 417 and a fourth post 418. When the computing component 420 is inserted in the support structure 400, the largest surface of the computing component 420 is parallel to the plate 410.

The resilient biasing element (not shown in FIG. 4) exerts a reaction force to the computing component 420 through the posts when the computing component 420 is positioned between the set of the first post 415 and third post 417 and the set of the second post 416 and the fourth post 418. In some examples, the upper set of posts is referred to as first set and the lower set of posts is referred to as second set. In an example, the posts comprise grommets so that the vibrations of the computing component 420 are not transmitted to the support structure 400. In other examples, the posts may comprise a vibration absorbent material.

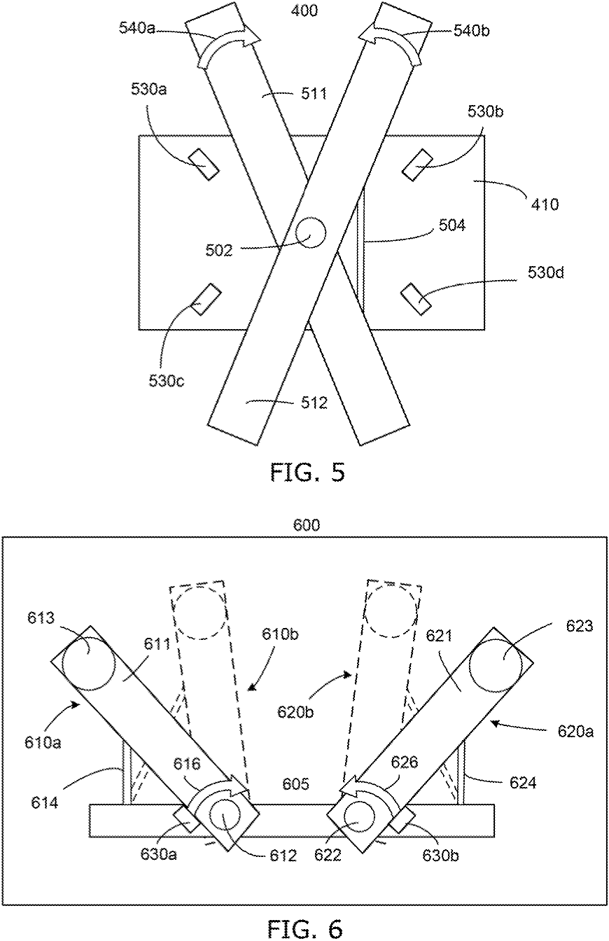

Referring now to FIG. 5, a rear view of the support structure 400 is shown. The support structure 400 comprises a pivot element 502 which enables the rotation of a first arm 511 and a second arm 512. The arms comprise the posts previously described in other examples. The support structure 400 further comprises a resilient biasing element 504 attached to the first arm 511 and the second arm 512. In other examples, further resilient biasing elements and/or attachments of the elements may be used, for instance, each of the arms being attached to a resilient biasing element that is attached in its opposite end to the plate 410.

In the example of FIG. 5, the plate 410 of the support structure 400 comprises a series of protruding elements 530a, 530b, 530c, and 530d on a second side of the plate 410. The protruding elements 530a, 530b, 530c, and 530d are to contact the arms, and therefore, the elements limit the rotation of each of the first arm 511 and the second arm 512. As a consequence, a rotation range is prevented for each of the arms. In FIG. 5, the protruding elements 530a, 530b, 530c, and 530d are distributed symmetrically relative to the longitudinal direction of the plate 410 that crosses the pivot element 502. However, other configurations may be possible.

When forces to bring together the first arm 511 and the second arm 512 are applied, the first arm 511 rotates in a first direction 540a and the second arm 512 rotates in a second direction 540b. As a consequence, the resilient biasing element 504 deforms and an available distance between the first set of posts and the second set of posts of the support structure 400 increases. When the forces are released, the resilient biasing element 504 recovers its original shape and therefore the first arm 511 and the second arm 512 rotate back to their original configuration. If a storage drive is inserted during a deformation of the resilient biasing element 504, the posts support the computing component in place upon the force is released. In other examples, the resilient biasing element biases the first arm 511 and the second arm 512 laterally to the pivot element 502 in a direction towards engagement with the computing component such that the first post and the third post contact a first lateral side of the computing component and the second post and the fourth post contact a second lateral side of the computing component to hold the computing component in place.

In other examples, the support structure may comprise other configurations. By combining elements of the previous examples, different configurations to removably support a computing component are obtained.

Referring now to FIG. 6, an inner surface 600 of a device housing and a support structure 605 are shown in an alternative arrangement. The support structure 605 is to support a computing component (not shown in FIG. 6). In other examples, the support structure is disposed at a different position within an inner volume of a computing device housing. The support structure 605 comprises a first arm 611 and a second arm 621. Each of the first arm 611 and the second arm 621 are attached at one of their ends to a first pivot element 612 and a second pivot element 622, respectively. Therefore, the first arm 611 is rotatable about the first pivot element 612 and the second arm 621 is rotatable about the second pivot element 622. The opposite end of the arms comprise a first post 613 and a second post 623, respectively. The first arm 611 comprises the first post 613 and the second arm 621 comprises the second post 623.

In the example of FIG. 6, the first arm is attached to a first resilient biasing element 614 and the second arm 621 is attached to a second resilient biasing element 624. The resilient biasing elements enable to bias both arms laterally so that the first post 613 and the second post 623 hold a computing component in place. The first post 613 and the second post 623 may contact a first side of the computing component. The contacts between posts and the computing component may be defined as engagement. In other examples, the resilient biasing elements bias the first arm in a direction towards engagement with the computing component such that the first post 613 and the second post 623 contact a first lateral side of the computing component to hold the computing component in place. In some other examples, the first arm 611 and the second arm 621 may rotate about a single pivot element instead of having the first pivot element 612 and the second pivot element 622.

The rotation of each of the arms may be restricted by protruding elements. In FIG. 6, a first protruding element 630a and a second protruding element 630b are positioned so that the rotation of the arms is prevented outside a rotation range. The protruding elements limit the rotation of each of the first arm 611 and the second arm 621. In other examples, the support structure may not comprise protruding elements.

In the example of FIG. 6, the first arm 611 is in a first position 610a and the second arm 621 is in a second position 620a. Both resilient biasing elements are in a relaxed state, and hence, no biasing force is applied. In case that the first post 613 and the second post 623 are pulled together, the resilient biasing elements deform. As a consequence, biasing forces may be applied by the resilient biasing elements.

As illustrated in FIG. 6, pulling together the first post 613 and the second post 623 causes the first arm 611 and the second arm 621 to rotate relative to its respective pivot element. A clockwise rotation 616 changes the position of the first arm 611 to a first arm second position 610b. A counterclockwise rotation 626 changes the position of the second arm 621 to a second arm second position 620b. For illustrative purposes, a first arm second position 610b and a second arm second position 620b are drawn in dashed lines. The first arm 611 and the second arm 621 may be referred to as being rotatable about axes perpendicular to the largest face of the computing component. In some examples, the first arm 611 and the second arm 621 are rotatable about an axis perpendicular to the largest face of the computing component.

However, in other examples, different configurations of the support structure may be used to support a computing component. As previously explained in reference to other examples, support structures may be disposed within inner volumes of device housings. The device housing may be, for instance, the device housing of a computing device. In an example, the support structure comprises a single rotatably mounted arm comprising a first post. The arm may be rotatable about an axis perpendicular to the largest face of a computing component which may be, for instance, a storage drive. The support may further comprise a resilient biasing element attached to the arm to bias the first arm laterally so that the first post can hold the computing component in place. The arm may rotate about a pivot element. The resilient biasing element may bias the first arm in a direction towards engagement with the computing component such that the first post contacts a first lateral side of the computing component to hold the computing component in place.

What has been described and illustrated herein are examples of the disclosure along with some variations. The terms, descriptions, and figures used herein are set forth by way of illustration only and are not meant as limitations. Many variations are possible within the scope of the disclosure, which is intended to be defined by the following claims (and their equivalents) in which all terms are meant in their broadest reasonable sense unless otherwise indicated.

What is claimed is:

1. A device housing having a support structure to hold a removably mounted computing component, the support structure comprising:
a first rotatably mounted arm comprising a first post, wherein the first arm is rotatable about an axis perpendicular to the largest face of the computing component; and
a resilient biasing element attached to the first arm, the resilient biasing element to bias the first arm in a direction towards engagement with the computing component such that the first post holds the computing component in place.

2. The device housing as claimed in claim 1, wherein the support structure further comprises:
a second rotatably mounted arm comprising a second post, wherein the second arm is rotatable about the axis perpendicular to the largest face of the computing component; and
a second resilient biasing element to bias the second arm in a direction towards engagement with the computing component such that the second post holds the computing component in place.

3. The device housing as claimed in claim 2, wherein the support structure comprises a plurality of protruding elements to limit a rotation of each of the first arm and the second arm.

4. The device housing as claimed in claim 1, wherein the first arm further comprises a second post, wherein the support structure further comprises:
a second rotatably mounted arm comprising a third post and a fourth post,
wherein the first arm and the second arm are rotatable about a pivot element, and
wherein the resilient biasing element is further attached to the second arm so that the first post, the second post, the third post, and the fourth post hold the computing component in place.

5. The device housing as claimed in claim 4, wherein the support structure further comprises a plate to contact the computing component, wherein the plate comprises a vibration absorbent material.

6. A computing device comprising:
a device housing;
a storage drive, and;
a support structure disposed within an inner volume of the device housing, wherein the support structure comprises:
a first arm comprising a first post and rotatable about a first pivot element; and
a first resilient biasing element attached to the first arm to bias the first arm laterally to the first pivot element in a direction towards engagement with the storage drive such that the first post contacts a first lateral side of the storage drive to hold the storage drive in place.

7. The computing device as claimed in claim 6, wherein the support structure further comprises:
a second rotatable arm comprising a second post and rotatable about a second pivot element; and
a second resilient biasing element attached to the second arm to bias the second arm laterally to the second pivot element in a direction towards engagement with the storage drive such that the second post contacts the first lateral side of the storage drive to hold the storage drive in place.

8. The computing device as claimed in claim 7, wherein the first pivot element and the second pivot element are a single pivot element.

9. The computing device as claimed in claim 6, wherein the first arm further comprises a second post and the support structure further comprises:
a second rotatable arm comprising a third post and a fourth post, wherein the second arm is rotatable about the first pivot element,
Wherein the resilient biasing element is attached to the second arm, wherein the first and the third post contact the first lateral side of the storage drive and the second and the fourth post contact a second lateral side of the storage drive.

10. The computing device as claimed in claim 9, wherein the support structure further comprises a plate, wherein the plate comprises a vibration absorbent material on a first side to contact the storage drive.

11. The computing device as claimed in claim 10, wherein the plate comprises a series of protruding elements on a second side to contact the first arm and the second arm, wherein the series of protruding elements limit a rotation of each of the first arm and the second arm.

12. A device housing to support a computing component, comprising:
an inner surface; and,
a support structure attached to the inner surface, wherein the support structure comprises:
a first arm comprising a first post in one of its ends, wherein the first arm rotates about a first pivot element;
a second arm comprising a second post in one of its ends, wherein the second arm rotates about a second pivot element; and, and,
a first resilient biasing element attached to the first arm; and,
a second resilient biasing element attached to the second arm,
wherein deformation of the first biasing element causes to transmit a first reaction force to the computing component through the first post, wherein a deformation of the second biasing element causes to transmit a second reaction force to the computing component through the second post.

13. The device housing as claimed in claim 12, wherein the first arm further comprises a second post in its opposite end and the second arm further comprises a fourth post in its opposite end, wherein the first reaction force and the second reaction force are transmitted to the computing component through each of the first post, second post, third post, and fourth post.

14. The device housing as claimed in claim 13, wherein the first arm and the second arm are rotatable about a single pivot element.

15. The device housing as claimed in claim 13, wherein the support structure further comprises a plate attached to the first pivot element, wherein the plate and the posts comprise vibration absorbent materials.
